(19) United States
(12) Patent Application Publication
(10) Pub. No.: US 2016/0054391 A1
(43) Pub. Date: Feb. 25, 2016

(54) METHOD, DEVICE AND SYSTEM FOR MEASURING IMPEDANCE OF FUEL CELL

(71) Applicants: Hyundai Motor Company, Seoul (KR); Kia Motors Corporation, Seoul (KR)

(72) Inventors: Sangbok Won, Seoul (KR); Kwiseong Jeong, Yongin (KR)

(21) Appl. No.: 14/555,822

(22) Filed: Nov. 28, 2014

(30) Foreign Application Priority Data
Aug. 22, 2014 (KR) 10-2014-0109925

(51) Int. Cl. G01R 31/36; H01M 8/04

(52) U.S. Cl. CPC G01R 31/3662; H01M 8/04641; G01R 31/3655

(57) ABSTRACT

Disclosed are a method, a device and a system for measuring impedance of a fuel cell. For example, the method includes: injecting, by an impedance measurement device, a current of an associated wave to the fuel cell; receiving, by the impedance measurement device, a voltage in response to the current of the associated wave from the fuel cell; and measuring, by the impedance measurement device, impedance of the fuel cell using the current of the associated wave and the response voltage. In particular, the associated wave used in the method, the device and the system is a nonsinusoidal periodic wave.

### CROSS-REFERENCE TO RELATED APPLICATION

This application claims priority to and the benefit of Korean Patent Application No. 10-2014-0109925 filed in the Korean Intellectual Property Office on Aug. 22, 2014, the entire contents of which are incorporated herein by reference.

### TECHNICAL FIELD

The present invention relates to a method, a device, and a system for measuring impedance of a fuel cell. In particular, impedance of a fuel cell may be measured using a nonsinusoidal periodic wave such as a rectangular wave.

### BACKGROUND

A fuel cell is a power generation device which directly converts chemical energy generated by oxidizing a fuel into electrical energy. The fuel cell is the same as a chemical battery in that it basically uses an oxidation and reduction reaction, but has a difference from the chemical battery. For example, in the fuel cell, reactants are continuously supplied from the exterior and reaction products are continuously removed to the exterior of a system, in contrast, battery reaction of the chemical battery is performed in a closed system. Currently, since the reaction by-products of the fuel cell is pure water, research for using the fuel cell as a power source of an eco-friendly vehicle has been actively made.

The above-mentioned fuel cell may be applied to supply power of small electric and electronic products as well as to supply industrial, home, and vehicle driving power

For example, as a power supply source for driving the vehicle, a polymer electrolyte membrane fuel cell (PEMFC) having the greater power density among fuel cells has been substantially developed. The polymer electrolyte membrane fuel cell requires less start time due to its low operation temperature and less power conversion reacting time.

The polymer electrolyte membrane fuel cell may include a membrane electrode assembly (MEA), which includes catalytic electrode layers attached to both sides of a solid polymer electrolyte membrane in which hydrogen ion is moved and perform an electrochemical reaction, a gas diffusion layer configured to uniformly distribute reaction gases and transmit the generated electric energy, and a bipolar plate configured to provide flow paths for the reaction gases and coolant.

The fuel cell is configured by a stack assembly in which unit cells are continuously disposed, which is referred to as a fuel cell stack. The electric energy is generated when hydrogen as fuel and oxygen as oxidizing agent react in the unit cells of the cell stack. When performance degradation or fail occurs in any one of unit cells included in the fuel cell stack, the entire performance of the fuel cell stack may be degraded, thereby causing failure of a stable operation.

Performance of the fuel cell stack is diagnosed by measuring a voltage output from each unit cell of the fuel cell stack, and an exemplary diagnosis method may be a total harmonic distortion analysis (THDA) method. The THDA method calculates a distortion rate by analyzing a frequency of a stack voltage to thereby diagnose a cell voltage. According to the THDA method the cell voltage drop may be easily detected, but reasons of the drop in the cell voltage may not be measured quantitatively.

In addition, a method for measuring impedance of the fuel cell stack using electrochemical impedance spectroscopy (EIS) has been developed. According to the EIS method, a current or voltage of a sine wave is supplied to the fuel cell stack, a current I and a voltage V of the fuel cell stack are then measured, and impedance is calculated based on the measured current and voltage.

The above information disclosed in this Background section is only for enhancement of understanding of the background of the invention and therefore it may contain information that does not form the prior art that is already known in this country to a person of ordinary skill in the art.

### SUMMARY OF THE INVENTION

In a preferred aspect, the present invention provides a method, a device, and a system for measuring impedance of a fuel cell using a nonsinusoidal periodic wave such as a rectangular wave.

In an exemplary embodiment, a method for measuring impedance of a fuel cell may include: injecting, by an impedance measurement device, a current of an associated wave to the fuel cell; receiving, by the impedance measurement device, a voltage in response to the current of the associated wave from the fuel cell; and measuring, by the impedance measurement device, impedance of the fuel cell using the current of the associated wave and the response voltage.

In particular, the associated wave may be a nonsinusoidal periodic wave. For example, the current of the associated wave may be a current of a rectangular wave, a triangular wave, or a sawtooth wave.

The rectangular wave may have a duty rate of about 1% or greater and of about 10% or less under the conditions that power for generating the rectangular wave is the same or under a constant power. The rectangular wave may have a duty rate of about 50%, about 25%, about 20%, or about 5%.

In an exemplary embodiment, a device for measuring impedance of a fuel cell may include: a signal generating unit configured to generate a current of an associated wave applied to the fuel cell; a signal receiving unit configured to receive a voltage in response to the current of the associated wave from the fuel cell; and an impedance measuring unit configured to measure impedance of the fuel cell using the current of the associated wave and the response voltage.

In particular, the associated wave may be a nonsinusoidal periodic wave. For example, the current of the associated wave may be a current of a rectangular wave, a triangular wave, or a sawtooth wave.

In an exemplary embodiment, a system for measuring impedance of a fuel cell may include: the fuel cell connected to an electrical load; an impedance measurement device configured to inject a current of an associated wave to the fuel cell, to receive a voltage in response to the current of the associated wave from the fuel cell, and then measure impedance of the fuel cell using the current of the associated wave and the response voltage; and a controller configured to receive an impedance measurement result information from the impedance measurement device.

In particular, the associated wave may be a nonsinusoidal periodic wave. As described above, the current of the associated wave may be a current of a rectangular wave, a triangular wave, or a sawtooth wave.

The rectangular wave may have a duty rate of about 1% or greater and about 10% or less under the conditions that power for generating the rectangular wave is the same. The rectangular wave may have a duty rate of about 50%, about 25%, about 20%, or about 5%.

Further provided are vehicles including automotive vehicles that use or comprise the device, the method and the system for measuring impedance of the fuel cell described herein.

According to various exemplary embodiments of the present invention, since the method, the device, and the system for measuring impedance of the fuel cell may measure impedance of the fuel cell using one nonsinusoidal periodic wave such as the rectangular wave (square wave), impedance of the fuel cell may be measured more efficiently than a conventional method for measuring impedance of the fuel cell using alternating currents of a plurality of sine waves.

In addition, since the method, the device, and the system for measuring impedance of the fuel cell measure impedance of the fuel cell using the nonsinusoidal periodic wave such as the rectangular wave, impedance measurement of the fuel cell may be simplified and reliability may be improved.

For example, a measuring alternating current control may be simplified by changing a waveform the measuring alternating current from the sine wave to the nonsinusoidal periodic wave which may generate and include a high frequency alternating current.

Moreover, the nonsinusoidal periodic wave may be defined with Fourier transform or Fourier series, and thus may be represented by a sum of a plurality of sine waves. Since one nonsinusoidal periodic wave is used as the measuring current, the number of measuring alternating currents may be reduced. As a result, amplitude of the measuring alternating current and robustness of a phase control may be improved.

### BRIEF DESCRIPTION OF THE DRAWINGS

A simple description of the drawings will be provided to more sufficiently understand the drawings which are used in the detailed description of the present invention.

FIG. 1 shows an alternating current injected into a fuel cell for measuring alternating current impedance in a time domain and a frequency domain in the related arts.

FIG. 2 shows an alternating current for measuring impedance used in an exemplary method for measuring impedance of a fuel cell and a frequency spectrum corresponding to the alternating current according to an exemplary embodiment of the present invention.

FIG. 3 shows an exemplary standard deviation of impedance measured values according to adjustment of a duty rate of a rectangular wave shown in FIG. 2.

FIG. 4 is an exemplary table describing the standard deviation of the impedance measured values according to the adjustment of the duty rate of the rectangular wave shown in FIG. 2.

FIG. 5 is an exemplary table describing frequency region values of the rectangular wave according to the adjustment of the duty rate of the rectangular wave.

FIG. 6 is an exemplary graph showing frequency region values of a sine wave in contrast to the adjustment of the duty rate of the rectangular wave according to an exemplary embodiment of the present invention.

FIGS. 7 to 17 are exemplary graphs showing the frequency region values of the rectangular wave depending on duty rate values of the rectangular wave according to various exemplary embodiments of the present invention.

FIG. 18 illustrates an exemplary system to which an exemplary method for measuring impedance of the fuel cell is applied according to an exemplary embodiment of the present invention.

FIG. 19 is a graph showing an example of an impedance measured value when alternating currents of the rectangular wave and the sine wave are input to the exemplary system of FIG. 18 according to an exemplary embodiment of the present invention.

FIG. 20 is a graph showing an example of the impedance measured value when the alternating currents of the rectangular wave and the sine wave are input to the system of FIG. 18 according to an exemplary embodiment of the present invention.

FIG. 21 illustrates an exemplary impedance measurement device shown in FIG. 18 according to an exemplary embodiment of the present invention.

FIG. 22 illustrates an exemplary fuel cell shown in FIG. 18 according to an exemplary embodiment of the present invention.

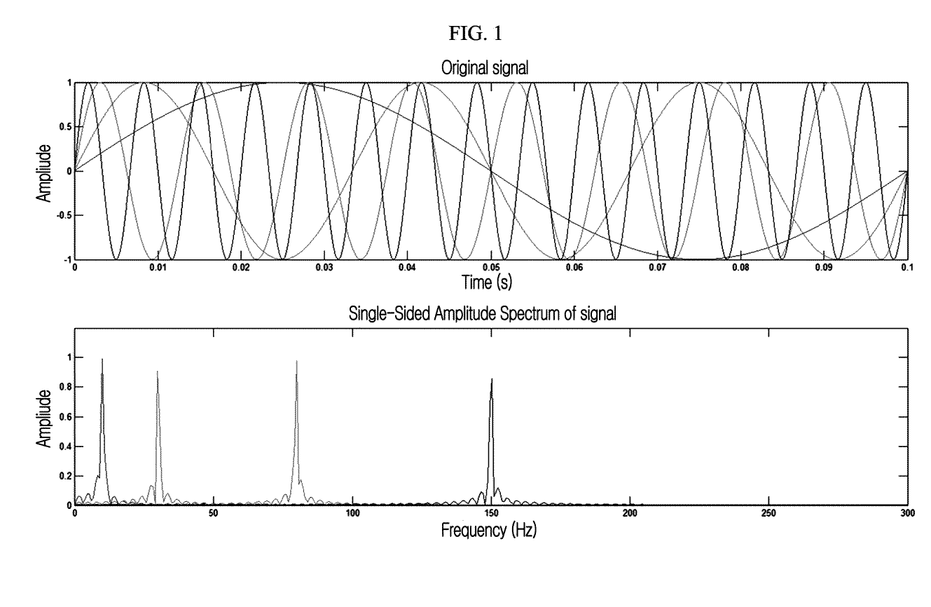

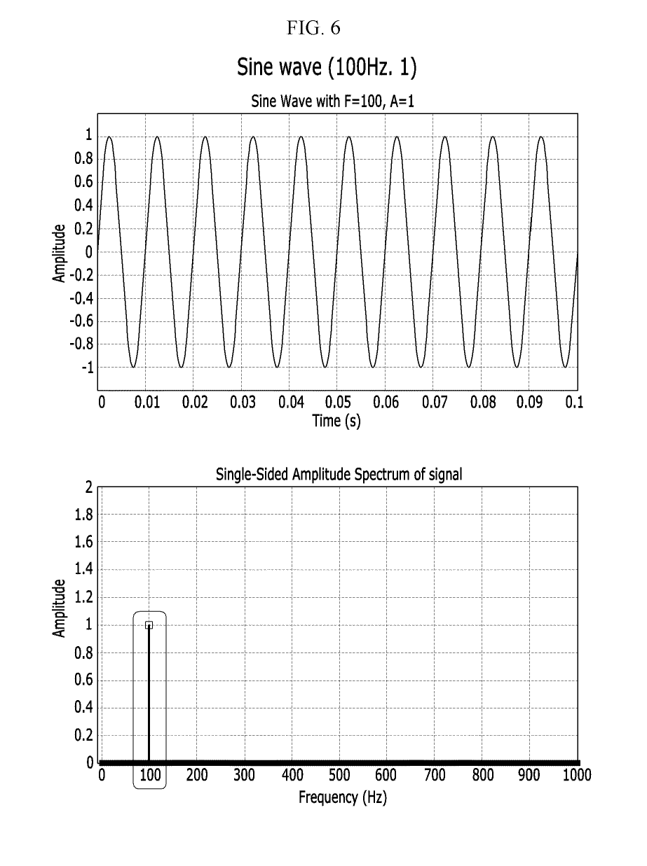

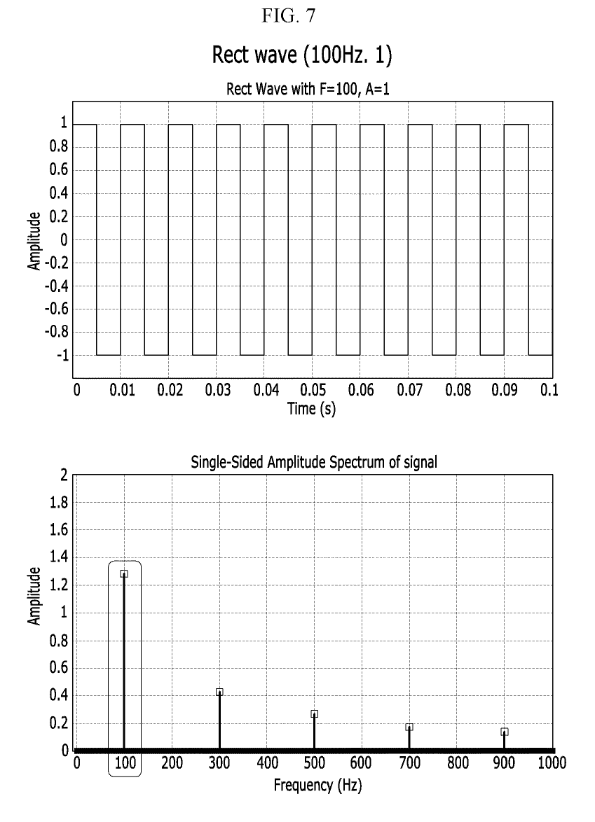

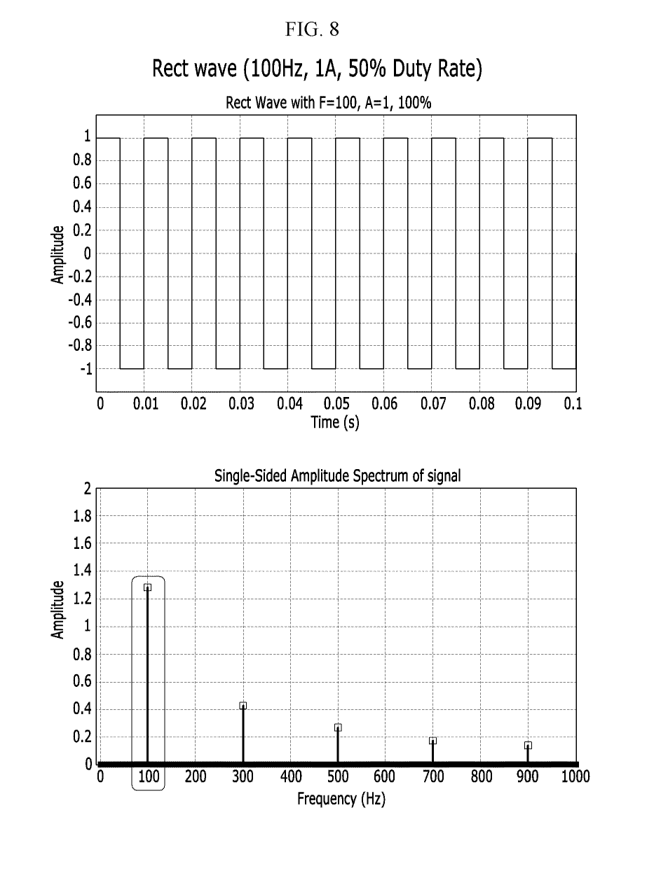

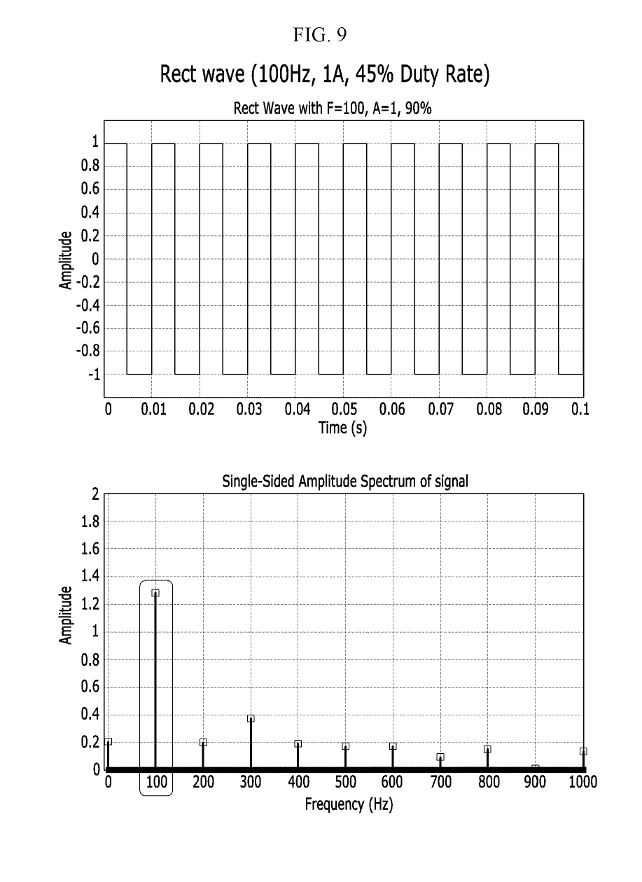

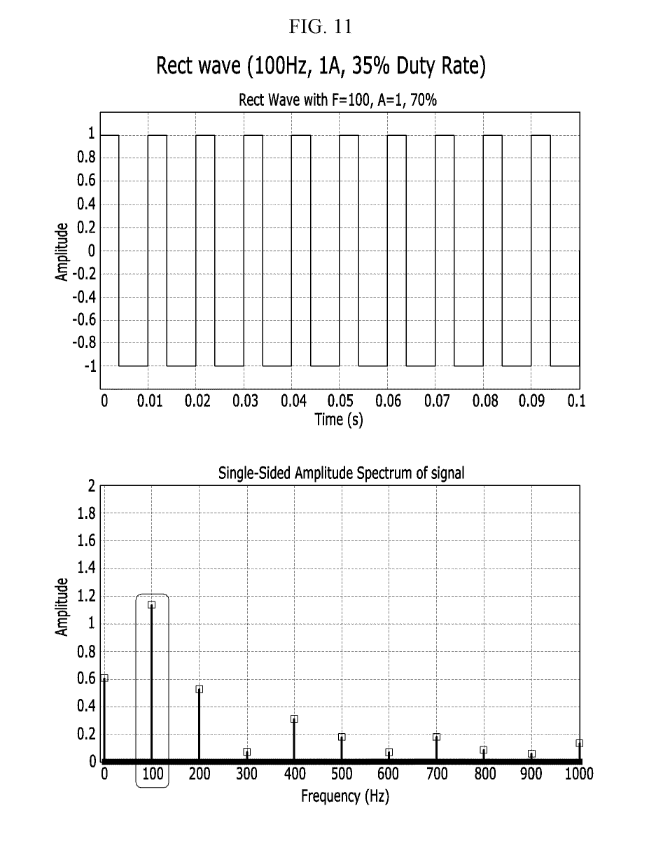

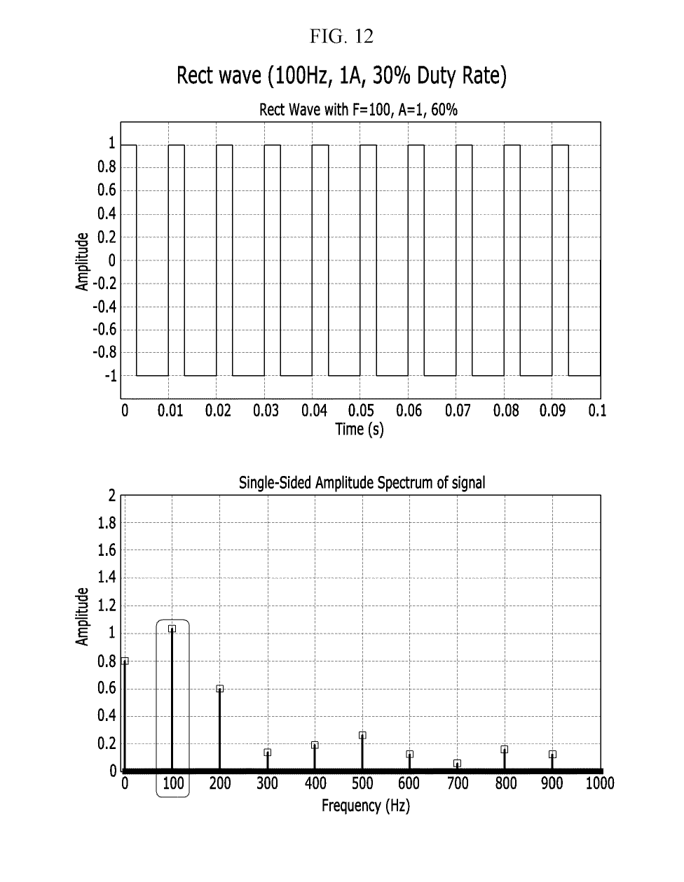

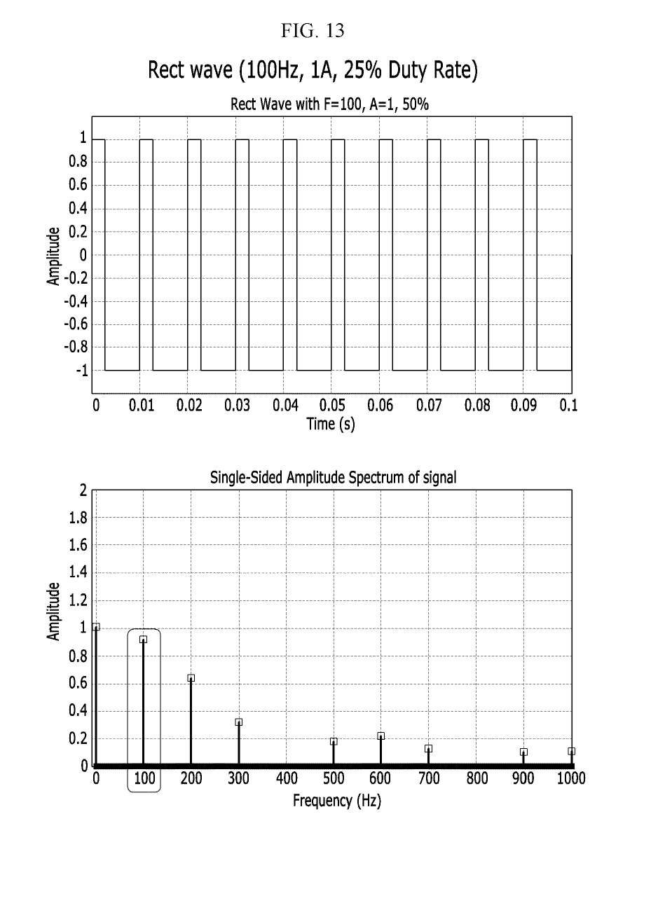

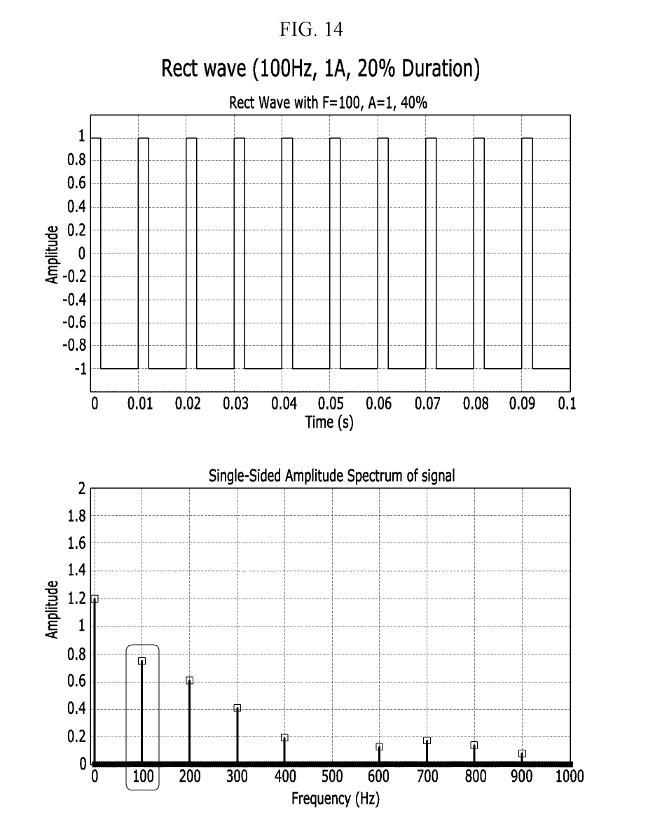

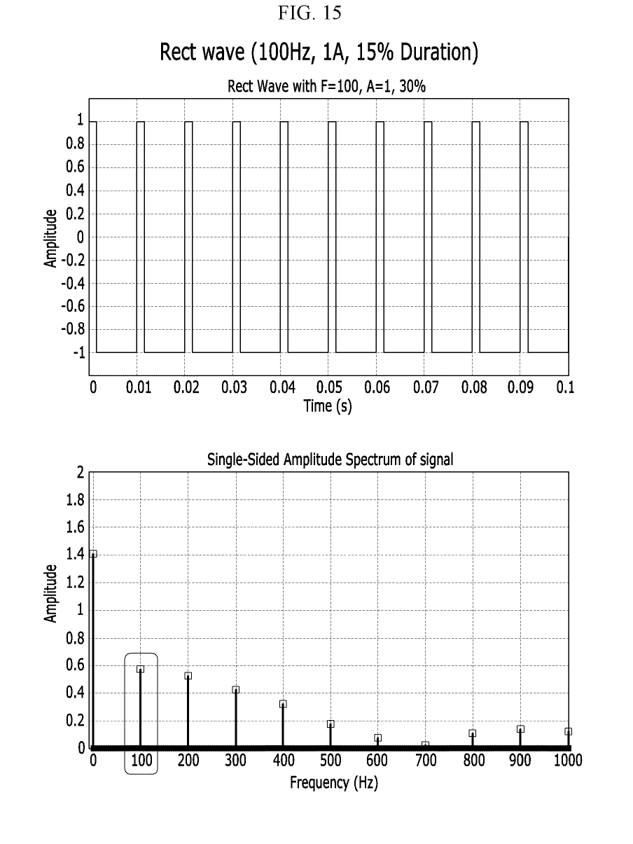

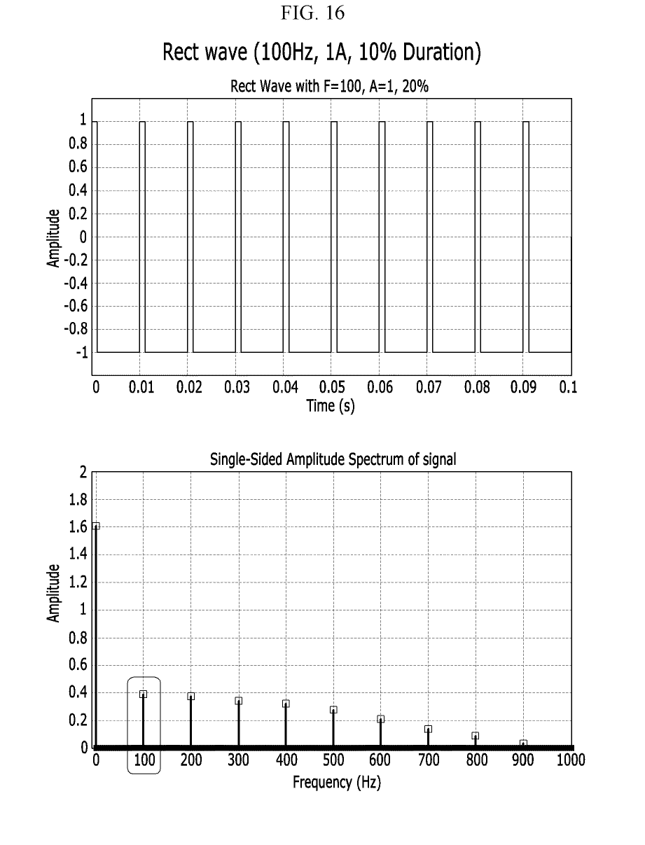

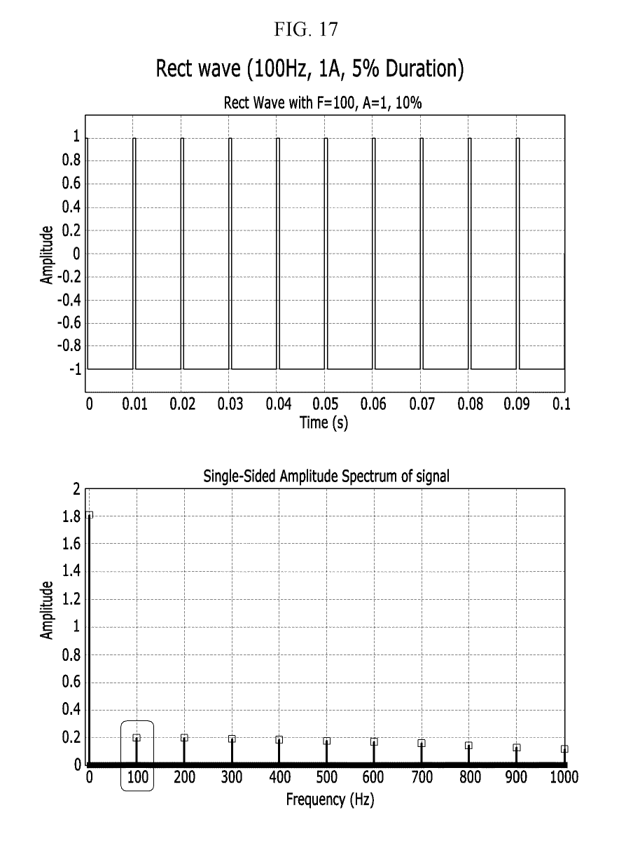

Reference numerals set forth in the FIGS. 1-22 include reference to the following elements as further discussed below:

105: fuel cell

110: electrical load

115: controller

200: impedance measurement device

205: signal generating unit

210: signal receiving unit

215: impedance measuring unit

### DETAILED DESCRIPTION

In order to sufficiently understand the present invention and the object achieved by embodying the present invention, the accompanying drawings illustrating exemplary embodiments of the present invention and contents described in the accompanying drawings are to be referenced.

Hereinafter, the present invention will be described in detail by describing exemplary embodiments of the present invention with reference to the accompanying drawings. In describing the present invention, well-known functions or functions will not be described in detail since they may unnecessarily obscure the gist of the present invention. The same reference numeral present in the respective drawings may indicate the same component.

Terms used in the present specification are merely used to describe a specific exemplary embodiment and are not intended to limit the present invention. Singular forms used herein are intended to include plural forms unless explicitly indicated otherwise. It will be understood that the term “comprises” or “have” used in this specification, specifies the presence of stated features, numerals, steps, operations, components, parts, or a combination thereof, but does not preclude the presence or addition of one or more other features, numerals, steps, operations, components, parts, or a combination thereof in advance.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

The term, “associated wave”, as used herein, refers to a waveform which may be represented a sum of the sine waves.

Although exemplary embodiment is described as using a plurality of units to perform the exemplary process, it is understood that the exemplary processes may also be performed by one or plurality of modules. Additionally, it is understood that the term controller refers to a hardware device that includes a memory and a processor. The memory is configured to store the modules and the processor is specifically configured to execute said modules to perform one or more processes which are described further below.

The components, or “˜ unit”, or block, or module used in the present exemplary embodiment may be implemented in software such as a task, a class, a subroutine, a process, an object, an execution thread, or a program which is performed in a predetermined region on the memory, or hardware such as a field programmable gate array (FPGA) or an application-specific integrated circuit (ASIC), and may be performed in a combination of the software and the hardware. The components, ‘˜ part’, or the like may be embedded in a computer-readable storage medium, and some thereof may be dispersedly distributed in a plurality of computers.

Unless indicated otherwise, it is to be understood that all the terms used in the specification including technical and scientific terms have the same meaning as those that are understood by those who skilled in the art. It must be understood that the terms defined by the dictionary are identical with the meanings within the context of the related art, and they should not be ideally or excessively formally defined unless the context clearly dictates otherwise.

Performance and lifespan of a fuel cell such as a polymer electrolyte fuel cell (PEFC) may be significantly influenced by operating conditions of the fuel cell. The operating conditions of the fuel cell may include a current, a temperature, an amount of a reaction material, a pressure of the reaction material, an amount of a cooling material, water content, and the like.

Accordingly, various state diagnosis methods of the fuel cell have been made in the art to optically control the operating conditions of the fuel cell described above based on a current state of the fuel cell. For example, the diagnosis method of the fuel cell may include an alternating current impedance measurement, a current and voltage curve measurement (current to voltage curve measurement), a catalyst area measurement, or the like.

The alternating current impedance measurement is configured to inject or apply alternating current signals of a few to several tens frequency regions to the fuel cell, measure the respective voltage responses, and then calculate impedance. The alternating current impedance measurement may be performed in a laboratory due to required measuring condition, such as a complex device, cost, and time, when the alternating signals of a few to several tens frequency regions necessary to measure impedance are generated and analyzed.

Further, in a method using a plurality of alternating currents when measuring impedance of the fuel cell, two or more alternating currents may be generated and injected to the fuel cell. Accordingly, a complex and precise power semiconductor control may be required. Since an impedance theory itself is based on a sine wave, the method for measuring alternating current impedance does not use an associated wave such as a rectangular wave.

FIG. 1 shows an alternating current injected into a fuel cell according to a method for measuring alternating current impedance in a time domain and a frequency domain in the related art.

In the method for measuring alternating current impedance, as shown in FIG. 1, a complex current control may be required to generate the alternating current, complexity of impedance measurement may be increased as number of injected currents increases, and robustness of measurement may be degraded.

Impedance has magnitude and phase components. In order to measure impedance of the fuel cell, when various frequencies of the injected alternating currents are used, improved computing capability to calculate magnitude and phase may be required.

In addition, magnitudes of a real part and an imaginary part of impedance are sensitively determined depending on the phase. When the impedance is measured in a vehicle with serious noise, robustness of the measurement may be significantly reduced. Accordingly, in the measurement method for injecting a plurality of alternating currents, when various alternating currents are used, robustness of the measurement may be degraded.

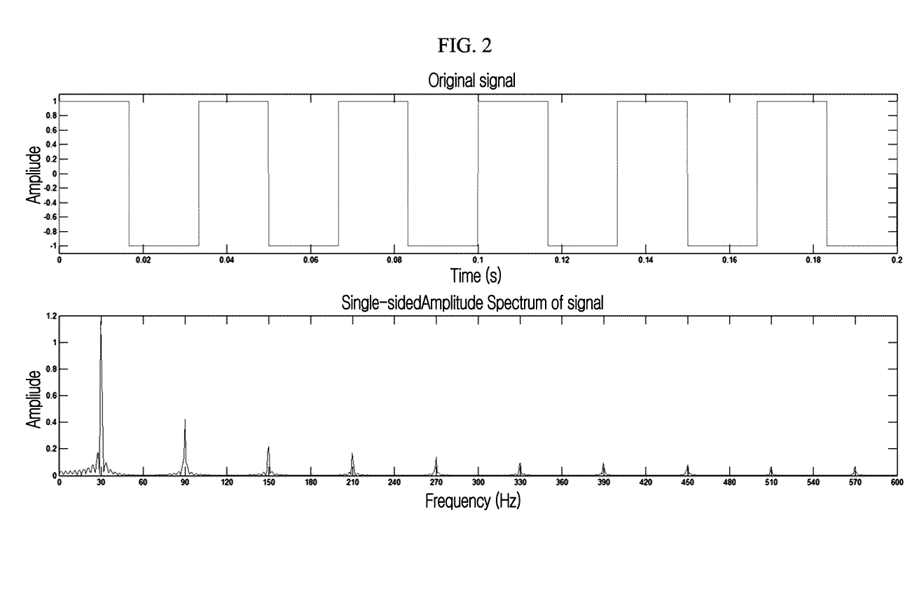

FIG. 2 shows a graph showing an alternating current for measuring impedance used in an exemplary method for measuring impedance of an exemplary fuel cell and a frequency spectrum corresponding to the alternating current according to an exemplary embodiment of the present invention.

According to the present invention, impedance of the fuel cell may be measured using a single associated wave such as a rectangular wave (square wave), a triangular wave, or a sawtooth wave having amplitude of 1 as shown in FIG. 2. Since the impedance theory itself is based on the sine wave, according to the present invention, a problem in the method for measuring alternating current impedance may be solved by using a nonsinusoidal periodic wave such as the rectangular wave (square wave). As such, the measurement of impedance of the fuel cell may be simplified and reliability may be improved.

In addition, the present invention is applied to a vehicle including the fuel cell, thereby impedance of the fuel cell may be measured efficiently.

Particularly, the alternating current for measuring impedance may not be generated in a sine wave form, but may be generated in a sum of the sine waves in the frequency domain such as the rectangular wave, the triangular wave, the sawtooth wave, or the like.

When the rectangular wave is used as the measuring alternating current, the same effect may be obtained as using a sine wave alternating current having a basic frequency together with sine wave alternating currents which is odd times of the basic frequency, all of which represent the rectangular wave. The above fact may be confirmed by the following Equation through Fourier series (or Fourier transform) of the rectangular wave.

$$\begin{matrix}\begin{matrix}{a}_{k} = \frac{1}{{T}_{0}} {\int }_{0}^{{T}_{0}} 1 \cdot {e}^{- j ( \frac{2 π}{{T}_{0}} ) kt} d t \\ = \frac{{e}^{- j π k} - 1}{- j 2 π k} , ( k \neq 0 ) \\ = \frac{1}{j π k} , ( k = \pm 1 , \pm 3 , \pm 5 , … )\end{matrix} & [ Equation ] \\ {a}_{0} = \frac{1}{2} & \end{matrix}$$

In the above Equation, aₖ and a₀ may indicate coefficients of Fourier series. The above Equation may indicate the coefficients of Fourier series of the rectangular wave having the magnitude which is changed to 0 and 1.

As may be confirmed in FIG. 2, the rectangular wave having a predetermined frequency in the time domain may be interpreted the sum of the sine waves of several frequencies in the frequency domain. As such, using one rectangular wave as a signal for measuring impedance may have the same effect as using several sine waves as the signal for measuring impedance.

The impedance measurement of the fuel cell may require a measurement signal which has substantial magnitude to improve reliability of the measurement. However, when the measurement signal is increased, power consumed to perform the measurement may be increased.

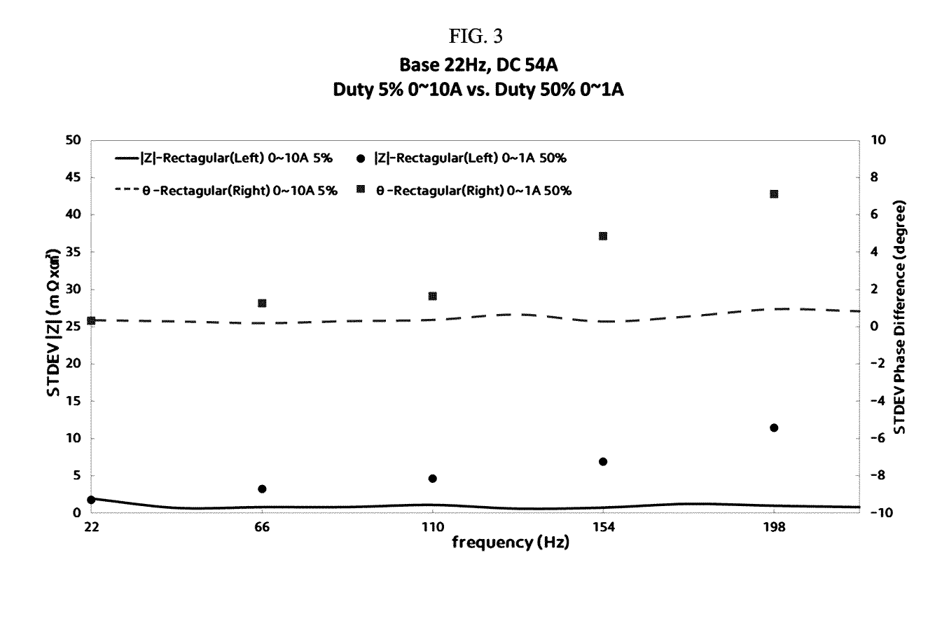

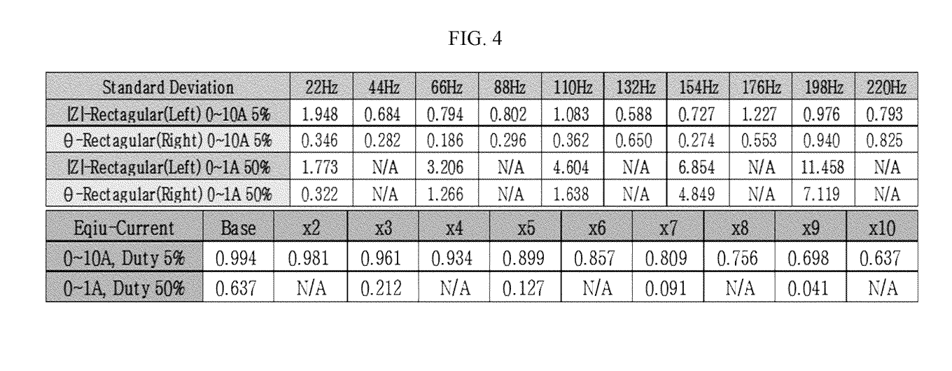

Accordingly to an exemplary embodiment of the present invention, by adjusting a duty rate of the rectangular wave used in the present invention, reliability of the measurement may be increased without increasing a power consuming amount, or energy used for the same measurement reliability may be reduced. As shown in FIGS. 3 and 4, reliability of the impedance measurement may be improved as amplitude of the measurement signal is increased. The duty rate may mean a ratio of a signal value 0 and a signal value 1 which are included in one period.

FIG. 3 is a drawing (graph) describing standard deviation of impedance measured values according to adjustment of a duty rate of a rectangular wave shown in FIG. 2 and FIG. 4 is a table describing the standard deviation of the impedance measured values according to the adjustment of the duty rate of the rectangular wave shown in FIG. 2.

As shown in FIGS. 3 and 4, when using the constant power, standard deviation of impedance measured values of duty of about 5%, 0 to 10(A), may be less than standard deviation of impedance measured values of duty of about 5%, 0 to 1(A) due to an amplitude difference of a sine equivalent current included in the rectangular wave.

According to an experiment of the present invention, the duty rate of an ideal measurement signal for minimizing impedance measurement reliability and consumption power may be from about 1 to about 10%. A general duty rate of the rectangular wave may be about 50%.

Particularly, when the power consumed amount of a device for measuring impedance for generating the rectangular wave are constant, and the duty rate of the rectangular wave is reduced, reliability of the impedance measurement may be improved. Alternatively, when reliability of the impedance measurement is constant and the duty rate is decreased, the power consumed amount of the device for measuring impedance may be reduced.

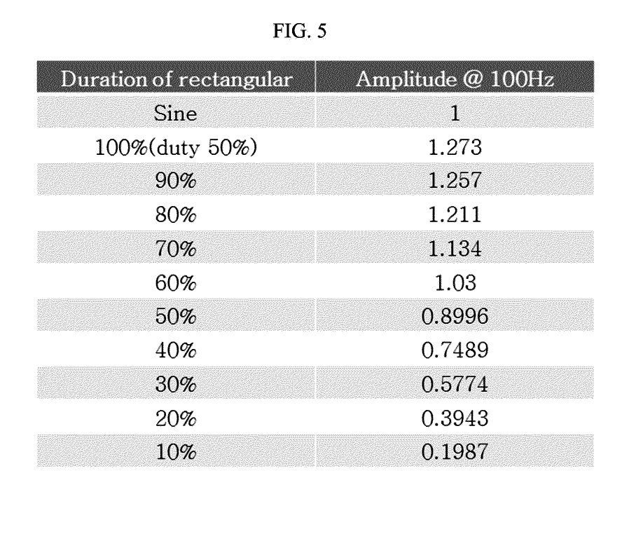

In addition, according to the present invention, as shown in FIGS. 5, and 7 to 17, by adjusting the duty rate of the rectangular wave, magnitudes of frequencies which are additionally generated in addition to the basic frequency may be adjusted. The duty rate of the measurement signal may be set as about 50%, about 25%, about 20%, or about 5%. For example, the duty rate of about 50% has the greatest amplitude of the basic frequency, the duty rates of about 25% and about 20% may observe a low frequency region and a high frequency region by comparing them with each other, and the duty rate of about 5% may uniformly observe frequency regions which are 1 to 10 times of the basic frequency.

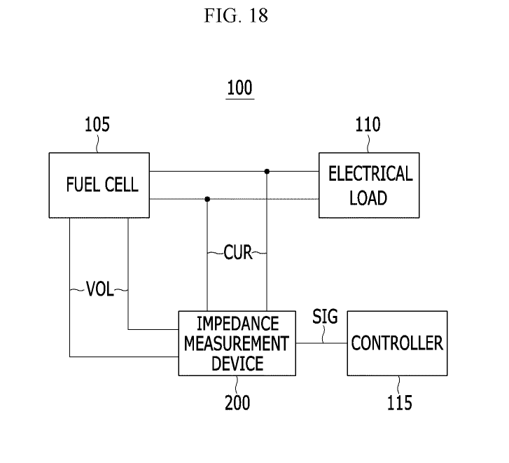

FIG. 18 is a block diagram describing an exemplary system to which an exemplary method for measuring impedance of the fuel cell according to an exemplary embodiment of the present invention is applied.

As shown in FIG. 18, a system for measuring impedance of a fuel cell may include a fuel cell 105, an electrical load 110, an impedance measurement device 200, and a controller 115.

The fuel cell 105 may be one unit cell, or a fuel cell stack in which a plurality of unit cells are connected in series with each other.

Electrical load 110 may include an electronic load, may be connected to the fuel cell 105, and may be a motor or the like.

The impedance measurement device 200 may inject an alternating current (CUR) of an associated wave to the fuel cell 105, and may measure an alternating current voltage (VOL). In particular, associated wave may be the nonsinusoical periodic wave. The impedance measurement device 200 may inject the current of the associated wave to the fuel cell 105, receive a response voltage in response to the current of the associated wave from the fuel cell 105, and then measure or calculated impedance of the fuel cell 105 using the current of the associated wave and the response voltage.

The impedance may be calculated by dividing Laplace transformation (or Fourier transform) of the response voltage by Laplace transformation (or Fourier transform) of the current of the associated wave, and both the response volatage and the current of the associated wave may be a time function. The current of the associated wave may be a current of the rectangular wave, the triangular wave, or the sawtooth wave shown in FIGS. 2 or 7 to 17.

Under the conditions in which power for generating the rectangular wave is constant, the duty rate of the rectangular wave may be about 1% or greater and about 10% or less, as mentioned in the description of FIGS. 3 and 4. The duty rate of the rectangular wave may be about 50% having the greatest amplitude of the basic frequency, may be about 25% and about 20% capable of observing a low frequency region and a high frequency region by comparing them with each other, or may be about 5% capable of observing frequency regions which are 1 to 10 times of the basic frequency.

The controller 115 may be a controlling device configured to receive impedance measurement result information from the impedance measurement device 200. The controller 115 may be configured to detect operation values of the fuel cell 105 through the impedance measurement result information. The operation value may include interior moisture content of the fuel cell 105, whether or not gas supplement is abnormal, or the like.

The controller 115 may be configured to determine whether the fuel cell is normal or abnormal by comparing the impedance measurement result information with a predetermined reference impedance. The reference impedance may be a threshold impedance value for a moisture state in which an electrolyte membrane of the fuel cell 105 may be normally operated, or a threshold impedance value by catalyst activity of the fuel cell 105. The reference impedance may be differently determined based on a user setting. When a membrane resistance of the electrolyte membrane of the fuel cell 105 or an activity resistance indicating the catalyst activity in the fuel cell 105 is compared to the reference impedance and the membrane resistance is greater than the reference impedance, it may be determined that the fuel cell 105 has abnormality.

The controller 115 may be configured to perform a function of a central processing unit (CPU) and may control the entire operation of the impedance measurement device 200. The controller 115 may include a program including a series of instructions for performing the method for measuring impedance of the fuel cell according to the present invention.

According to the present invention, impedance, which is a plurality of frequency responses, may be measured by inputting the alternating current of the associated wave which is the nonsinusoidal periodic wave such as one rectangular wave to the fuel cell 105. The nonsinusoidal periodic wave may include the triangular wave or the sawtooth wave. As described herein, the associated wave refers to a waveform which may be represented a sum of the sine waves.

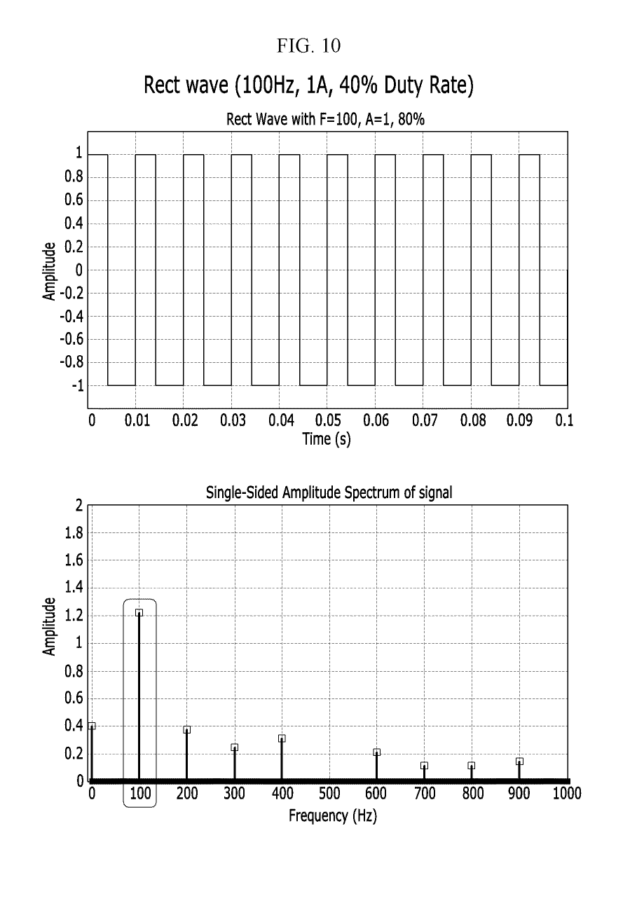

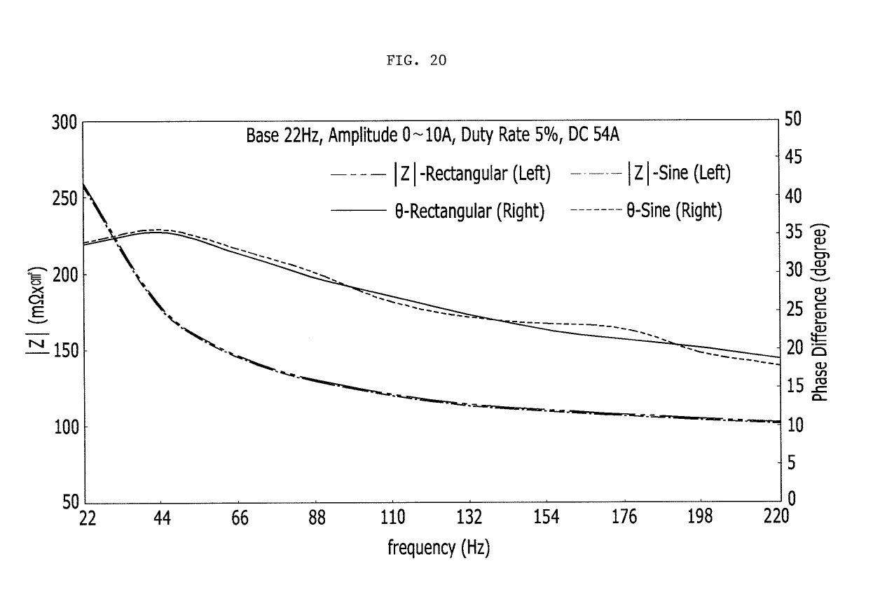

As shown in FIGS. 10 and 20, an experiment result obtained by measuring impedance of the fuel cell using one rectangular wave and a plurality of sine waves may have a tendency similar to absolute value but may have a difference within a measurement error. Accordingly, when the experiment data of the present invention are compared with experiment data of the method for measuring impedance of the fuel cell using the plurality of sine wave, since impedance measurement results from the plurality of sine waves and from one sine wave are same, the system for measuring impedance of the fuel cell may be substantially simplified and a used current may be reduced when the rectangular wave is used to measure impedance of the fuel cell.

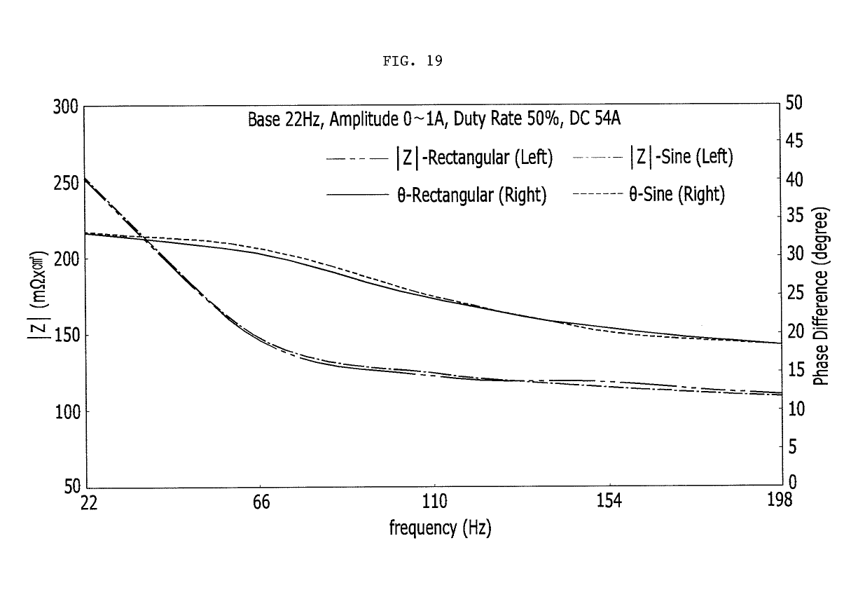

As shown in to FIG. 19, for the rectangular wave, impedances corresponding to about 22 Hz, about 66 Hz, about 110 Hz, about 154 Hz and about 198 Hz which are frequencies of about 1, about 3, about 5, about 7, and about 9 times of the basic frequency may be measured by using one signal having the basic frequency of 22 Hz. However, for the sine wave, only when all of 5 signals of about 22 Hz, about 66 Hz, about 110 Hz, about 154 Hz and about 198 Hz are used, the impedances of the corresponding frequencies may be measured in same manner.

In addition, as shown in FIG. 20, for the rectangular wave, impedances corresponding to about 22 Hz to about 220 Hz which are frequencies of about 1 to about 10 times of the basic frequency may be measured by using only one signal having the basic frequency of about 22 Hz. However, for the sine wave, only when all of 10 signals of about 22 Hz to about 220 Hz are used, the impedances of the corresponding frequencies may be measured.

Accordingly, according to the present invention, the plurality of sine waves may be substituted with the nonsinusoidal periodic wave such as the rectangular wave, thereby improving an impedance measurement function.

In addition, according to the present invention, since impedance of the fuel cell is measured by using one nonsinusoidal periodic wave, a part structure of the impedance measurement system or impedance measurement device may be simplified, such that production cost of the system may be reduced and robustness of the impedance measurement may be improved.

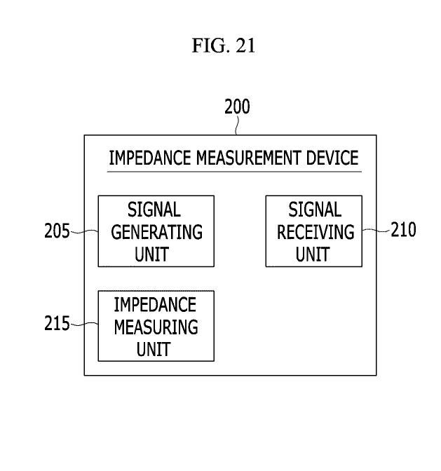

FIG. 21 illustrates an exemplary impedance measurement device shown in FIG. 18.

As shown in FIG. 21, the impedance measurement device 200 may include a signal generating unit 205, a signal receiving unit 210, and an impedance measuring unit 215.

The signal generating unit 205 may produce (generate) the current of the associated wave applied (input) to the fuel cell (105 in FIG. 18). The signal generating unit 205 may include a function generator capable of generating the current of the associated wave. In particular, the current of the associated wave may be the nonsinusoidal periodic wave such as the rectangular wave (square wave), the triangular wave, or the sawtooth wave.

The receiving unit 210 may receive a response voltage in response to the current of the associated wave from the fuel cell.

The impedance measuring unit 215 may measure or calculate impedance of the fuel cell using the current of the associated wave and the response voltage. The impedance may be calculated by dividing Laplace transformation (or Fourier transform) of the response voltage by Laplace transformation (or Fourier transform) of the current of the associated wave which is a time function. Herein, the response voltage and the current of the associated wave may be a time function.

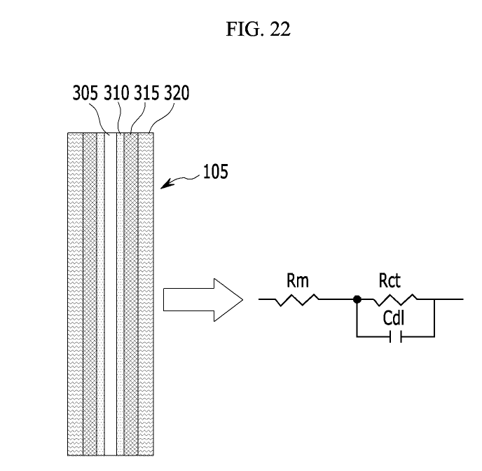

FIG. 22 illustrates an exemplary fuel cell shown in FIG. 18.

A longitudinal cross-section of one unit fuel cell 105 is shown in a left of FIG. 22. The fuel cell 105 such as a hydrogen fuel cell may include a hydrogen ion exchanging membrane 305 which is an electrolyte membrane, platinum catalytic layers 310 disposed on both external sides or surfaces of the hydrogen ion exchanging membrane 305, gas diffusion layers 315 disposed on both external sides of the platinum catalytic layer 310, and metal bipolar plates 320 disposed on both external sides of the gas diffusion layer 315. The gas diffusion layer 315 and the metal bipolar plate 320 may have a gas passage (not shown) disposed therebetween.

The fuel cell 105 may be presented as an electric circuit shown in a right of FIG. 22. Rm in the electric circuit may indicate an ohmic resistance which is the electrolyte membrane resistance of the fuel cell 105, Rct may indicate an activation resistance of the fuel cell, and Cdl may indicate electric double layer capacitance of the fuel cell.

Values of Rm, Rct and Cdl may be estimated or calculated by measuring the alternating current impedance of the fuel cell, and an internal state of the fuel cell 105 may be detected by the above-mentioned values.

As set forth above, the drawings and the specification have been disclosed. Herein, specific terms have been used, but are just used for the purpose of describing the present invention and are not used for qualifying the meaning or limiting the scope of the present invention, which is disclosed in the appended claims. Therefore, it will be understood by those skilled in the art that various modifications and equivalent exemplary embodiments are possible from the present invention. Accordingly, the actual technical protection scope of the present invention must be determined by the spirit of the appended claims.

What is claimed is:

1. A method for measuring impedance of a fuel cell, comprising:
injecting, by a controller, a current of an associated wave to the fuel cell;
receiving, by the controller, a voltage in response to the current of the associated wave from the fuel cell; and
measuring, by the controller, impedance of the fuel cell using the current of the associated wave and the response voltage,
wherein the associated wave is a nonsinusoidal periodic wave.

2. The method of claim 1, wherein the current of the associated wave is a current of a rectangular wave, a triangular wave, or a sawtooth wave.

3. The method of claim 2, wherein the rectangular wave has a duty rate of about 1% or greater, and a duty rate of about 10% or less under a constant power for generating the rectangular wave.

4. The method of claim 2, wherein the rectangular wave has a duty rate of about 50%, about 25%, about 20%, or about 5%.

5. A device for measuring impedance of a fuel cell, comprising:
a memory configured to store program instructions; and
a processor configured to execute the program instructions, the program instructions when executed configured to:
generate a current of an associated wave applied to the fuel cell;
receive a voltage in response to the current of the associated wave from the fuel cell; and
measure impedance of the fuel cell using the current of the associated wave and the response voltage,
wherein the associated wave is a nonsinusoidal periodic wave.

6. The device of claim 5, wherein the current of the associated wave is a current of a rectangular wave, a triangular wave, or a sawtooth wave.

7. A system for measuring impedance of a fuel cell, comprising:
the fuel cell connected to an electrical load;
an impedance measurement device configured to inject a current of an associated wave to the fuel cell, receive a voltage in response to the current of the associated wave from the fuel cell, and then measure impedance of the fuel cell using the current of the associated wave and the response voltage; and
a controller configured to receive an impedance measurement from the impedance measurement device,
wherein the associated wave is a nonsinusoidal periodic wave.

8. The system of claim 7, wherein the current of the associated wave is a current of a rectangular wave, a triangular wave, or a sawtooth wave.

9. The system of claim 8, wherein the rectangular wave has a duty rate of about 1% or greater and about 10% or less under a constant power for generating the rectangular wave.

10. The system of claim 8, wherein the rectangular wave has a duty rate of about 50%, about 25%, about 20%, or about 5%.

11. A vehicle using a method for measuring impedance of a fuel cell of claim 1.

12. A vehicle comprising a device for measuring impedance of a fuel cell of claim 5.

13. A vehicle comprising a system for measuring impedance of a fuel cell of claim 7.

14. A non-transitory computer readable medium containing program instructions executed by a controller, the computer readable medium comprising:
program instructions that generate a current of an associated wave applied to the fuel cell;
program instructions that receive a voltage in response to the current of the associated wave from the fuel cell; and
program instructions that measure impedance of the fuel cell using the current of the associated wave and the response voltage,
wherein the associated wave is a nonsinusoidal periodic wave.

15. The non-transitory computer readable medium of claim 14, wherein the current of the associated wave is a current of a rectangular wave, a triangular wave, or a sawtooth wave.
